(19) United States
(12) Patent Application Publication
(10) Pub. No.: US 2024/0248150 A1
(43) Pub. Date: Jul. 25, 2024

(54) MONITORING AN EVENT IN A POWER CONVERTER

(71) Applicant: Siemens Aktiengesellschaft, 80333 München (DE)

(72) Inventors: FABIAN HECHT, Lauf (DE); CORNEL-MARIAN ROSCA, Deining (DE)

(73) Assignee: Innomotics GmbH, Nürnberg (DE)

(21) Appl. No.: 18/029,311

(22) PCT Filed: Sep. 28, 2021
(86) PCT No.: PCT/EP2021/076569

§ 371 Date: Mar. 29, 2023

(30) Foreign Application Priority Data
Sep. 30, 2020 (EP) 20199337.5

(51) Int. Cl. G01R 31/40; G06N 20/00

(52) U.S. Cl. CPC G01R 31/40; G06N 20/00

(57) ABSTRACT

A method for monitoring an event in a power converter includes using record data after starting the power converter, wherein the record data do not indicate an error for a predetermined period of time after the power converter is started. Messages are assigned to error sources, and a degree of probability is calculated for an assigning process.

The invention relates to detecting critical events in a converter.

A converter renders it possible to achieve a variable speed operation of an electric machine, such as for example a motor. When the electric machine is used as a generator, a converter can also be used to convert the electrical current. This can be used, for example, to feed into the grid. When used as a motor, for example, the mains power which has a constant frequency and voltage is converted into a power that has a variable frequency and voltage.

The converter is, for example, a transducer, a rectifier or an inverter. The converter can be water-cooled and/or air-cooled. The converter is used, for example, in applications which place high demands on reliability and quality. Examples of applications for converters are for example:
industrial pumps and fans
oil and gas pumps and compressors, for example electric submersible pumps and high speed compressors
boiler blowers (induced draft and pressure ventilation) for power generation
clean water pumps and waste water pumps
applications using multiple motors and synchronous transfer (for example pipelines in the oil and gas industry).

These application examples often relate to a use of the converter where high power is required in particular. These are in particular powers in the single-digit, double-digit or triple-digit megawatt range. For this purpose, converters for medium voltage are preferably used. These are referred to as medium voltage converters. A voltage greater than or equal to 1000 V can be regarded as medium voltage. Voltages of 4000 V or 6000 V can also be considered medium voltage. The converter is, for example, a variable frequency drive (VFD). The Sinamics Perfect Harmony GH180 is an example of a VFD.

If the converter has problems, the problem is detected and documented or saved in a log file. The log file represents a log, in which the detected and documented problems are log entries. These log entries can be warnings to alert a user to potentially critical events. These log entries can also be faults to alert a user to a fault or to document this fault. Critical events are therefore also faults, for example. Fault messages or warning messages are thus generated for events. Faults can lead or have led to the failure of the converter. However, since a failure of the converter usually leads not only to a fault, but to a cascade of fault and warning log events, the technical cause of the failure of the converter is obscured and can only be deduced by converter experts who analyze the course of the log events.

One object of the invention is to improve an event monitoring of the converter.

The object is achieved by a method according to claim 1 or by a method according to claim 6 or in the case of event monitoring according to claim 10. Embodiments are disclosed, for example, in claims 2 to 5, 7 to 9 and 11.

In one method for event monitoring in a converter, log data of the converter is used, wherein prior to a start of the event monitoring the log data does not show a fault for a time period after the start, wherein the time period can be determined, wherein the converter has at least two types of faults or warnings, a first fault type or warning type, which depends on the type of converter, i.e. are determined in particular by the latter, and a second fault type or warning type, wherein the second fault type has faults or the second warning type has warnings, which can be defined by a user, i.e. are determined by the user, wherein for event monitoring an evaluation of a combination of faults or warnings of the respective first type and the respective second type is used, and/or for event monitoring an evaluation of a combination of faults or warnings of the respective second type are used. The converter can thus be designed, for example, by a user in such a manner that the user defines individual messages for the converter. An example of a message is a fault or a warning, i.e. a fault message or a warning message. The individual messages render it possible to create an individual event monitoring, which is dependent on the messages individually created by the user. This improves event monitoring and can make it more accurate. The messages defined by the user are, for example, stored in an SOP (System Operating Program) or defined there. Such user-defined messages can be labeled as such when the message is displayed. User-defined messages are based, for example, on signals from I/O interfaces that arise in a system in which the converter is integrated. Signals on which the user-defined messages are based can be, for example, digital signals or analogue signals. User-defined messages can be generated on the basis of, for example, a single signal and/or a combination of signals. Such signals can, for example, relate to an emergency stop, the opening of a door, the blowing of a fuse, an undervoltage, an overvoltage, a fault current, an overcurrent, a fan failure, a failure of a power module of the converter, the bypass of a power module of the converter, an insulation fault, an insulation warning, a communication fault, in particular of a power module of the converter, a fault or warning for cooling the converter, a pre-charging of the converter, etc. It can be seen that individually created messages are important for a converter which is integrated into an individual use (industrial plant). These messages that are created individually by a user can be used advantageously for event monitoring of the converter in its individual environment, i.e. the industrial plant. This improves the quality of the monitoring. The user of the converter is a person who operates the converter. This operation can be carried out, for example, by an operator of the converter or by a commissioning engineer or the like.

In one embodiment of the method, log data after a start of the converter, in particular a successful start of the converter, is used to generate event monitoring in a converter, wherein the log data does not show a fault for a time period after the start, wherein the time period can be determined. The converter is, for example, a medium voltage converter. The log data relates, for example, to status messages, warning messages and/or fault messages. Such messages relate, for example, to the following elements: a control of the converter, a regulation of the converter, a temperature sensor, an airflow sensor, an ammeter, a voltmeter, a power semiconductor, etc. A successful start of the converter is in particular a start during which fault messages and/or warning messages are not generated.

In one embodiment of the method, the log data is labeled, wherein the labeling is, in particular, temporal information such as a time stamp or relates to a sequence of logged messages, wherein a message is, in particular, a fault and/or a warning, wherein, in particular, log data is used after the start of the converter or after a reset of the converter.

In one embodiment of the method, a machine learning model, i.e. an artificial intelligence, is used. The artificial intelligence determines the most probable technical root causes of a failure or a fault in an automated manner. The artificial intelligence can be used to analyze a log event history in an automated manner. The log event history corresponds to the log data.

In one embodiment of the method, a machine learning algorithm is used which can categorize the technical root cause, i.e. the source, of a fault detected as such. Different steps can be performed for this purpose. In one step, failures of a historical batch of logbook data, which can also be referred to as log data, can be labeled by an expert. In another step, a machine learning algorithm can be trained to categorize fault events into predefined cause categories. Thus, a categorization into sources for faults takes place. The artificial intelligence can thus be trained so as on the basis of a cascade of messages (one or a multiplicity of: status messages, warning messages, fault messages) to infer a fault source, i.e. to indicate it. In one embodiment, several fault sources can also be indicated, whereby a probability for the correctness of this indication is calculated or output in each case.

In one embodiment of the method, the log data is thus labeled, wherein the labeling relates to a temporal sequence of logged messages. The log data has just these messages. The temporal sequence results from a cascading of messages. Such messages can be dependent on each other or independent of each other. The messages that are considered in their sequence are in particular of different types. They are therefore messages that are determined by the type of converter and messages that are determined by the user of the converter.

One object of the artificial intelligence is to detect interdependent messages and to allocate them to a causal source.

In one embodiment of the method, in one step, a database of historical data of one or more converters, in particular of the same type, is searched for faults in an automated manner. The faults are listed, for example, with the following information about the fault, i.e. distinguished from each other:
Faults that occurred during the failure up to 1 hour after the first fault. This time interval was designed for best results and is a typical period of time in which faults cause side effects or require human intervention to solve this problem; these faults relate for example to: an input-related fault (for example a problem in the power supply of the drive), a cooling system-related fault (for example a failure of the air or water cooling) and/or a power cell communication fault (for example an internal electronic drive system); the collected information contributes to the accuracy of the presented approach;
Warnings that occurred prior to the first fault, especially up to three hours prior to the first fault; this time interval ensures that the most critical information (messages) causally related to the fault are collected and selected after expert advice and engineering of the results; however, different time intervals could be chosen for different types of failures, since they are expected to have a different time until the failure; for cooling system-related faults, even a week of time could be important for root cause analysis (for example, a leak in the coolant can cause alarms days or weeks before the actual cooling system failure can be diagnosed);
The time between a first and a last fault; this time is important because it can separate failures of a combination of faults, which occur almost simultaneously and are therefore likely to be causally related, from a series of faults caused by human intervention.

In one embodiment of the method, messages are allocated to sources of faults. In this manner, it is possible to distinguish subsequent faults from a causal fault.

In one embodiment of the method, for training the artificial intelligence, information about the temporal sequence of messages and about a categorized causality is given to an expert who determines the root cause of each failure and labels it, for example, in a list as at least one of the following root cause categories, which in particular cover all critical components of the converter:
Power Cell (power cell/power semiconductor module)-related (for example, failure due to a power cell problem),
Power Cell communication-related (for example, failure due to power cell communication problems),
System-related,
Cooling-related (for example, failure due to a cooling system problem),
Input-related (for example faults due to problems in the input of an operator on site to drive the converter),
Power-related (for example, failure due to problems in the application driven by the drive),
Pre-charge-associated (for example, failure due to pre-charge problems when starting the converter),
Drive loss-associated (for example, failure due to excessive drive losses),
Manual stop (for example, cascades of faults triggered by manual shutdown of the drive).

In one embodiment of the method, a probability is calculated for an allocation. This allows a more targeted approach to rectifying a fault without forgetting possible but unlikely failure possibilities.

In one embodiment of the method, a list of faults, i.e. the log data, with expert labels is used as input to a machine learning algorithm in the sense of a supervised learning approach. The machine learning algorithm is optimized to be able to categorize previously unknown failures, returning categories with a categorization probability that is, for example, the root cause, i.e. the source of the failure: for example, cooling-related faults (90%), system-related faults (10%).

Thus, in one embodiment of the method, an artificial intelligence is trained and thus an event monitoring is generated.

In one method for event monitoring in a converter, messages are recorded, wherein the messages have a time stamp and an identification, wherein an event is detected by the sequence of the messages. It is possible to infer a certain causal fault source from a specific cascading, wherein causally related faults can be detected.

In one embodiment, a collection of data can be created by means of a digital platform, in particular in a cloud, for optimizing drive systems, motors and transducers. The data relates in particular to log files of corresponding machines, such as a converter or a motor or a transformer. This data can be used in particular to categorize the root cause of a selected fault using a machine learning algorithm. For example, logbook data obtained from a converter can have the following information:
the timestamp of the log event,
the severity of the log event: info, fault or warning,
a text of the log event,
the trigger of the log event.

Thus, for example, a failure of a drive is indicated by the occurrence of one or more faults after a certain fault-free time following a successful restart. Here, the fault-free time is defined as at least seven days. This is a characteristic time that was determined, for example, during development to ensure that the drive was in a regular operating mode. In this regard, the drive has at least one converter.

In one embodiment of the method, the identification includes a message type, a text and/or a source of the message. Uniqueness can be ensured in this manner.

In one embodiment of the method, the event is an output fault, wherein an artificial intelligence is used to detect the event, wherein the artificial intelligence is a cloud application. Thus, the same quality of artificial intelligence can always be used regardless of location.

In one embodiment of the method, event monitoring of the type described is used. Thus, the event monitoring of a converter can have and/or access artificial intelligence.

An event monitoring of a converter has a communication facility and data processing for carrying out one of the described methods.

It is now possible to extract the cause of the failure of a converter from the log events without in-depth technical knowledge. Until now, it was only possible for experts to analyze the log files of the converter and deduce the cause of a failure. As a result, the following is now possible, for example:
a user can quickly analyze the failure of their converter and get their application up and running again more quickly;
the user can check the failures of their drive, which has at least one converter, in the past in order to optimize their system for less downtime;
converters can be checked more easily and service measures can be suggested more easily;
a faster restart of a converter is possible, as the time for root cause analysis by experts is drastically reduced.

In contrast to manual analysis, the automated solution presented here is particularly capable of processing any number of faults simultaneously.

A cloud analysis approach is also rendered possible, since the log file data from the converter is stored in the cloud. As a result, root cause analysis, for example, is provided on scalable cloud instances in a suitable Python environment. These technical features contribute to the great advantage of the presented approach since they enable process automation.

In one embodiment of the invention, the machine learning approach (labeling) derived from expert knowledge is used as a key algorithm for the artificial intelligence algorithm, which is implemented as an automated root cause analysis module. In particular, fault extraction is based on historical data as well as expert labeling.

The features of the individual claimed or described subject matters can be readily combined with each other. In the following, the invention is illustrated and explained in more detail by way of example with reference to figures. The features shown in the figures can be expertly combined to form new embodiments without departing from the invention. In the figures:

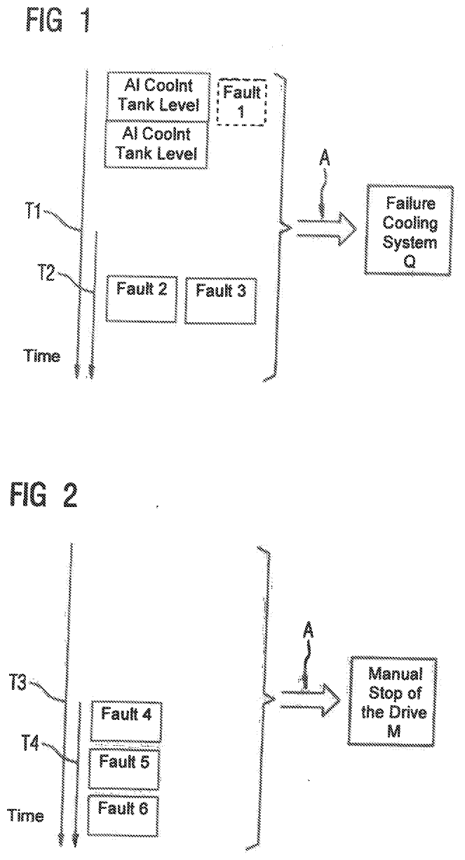

FIG. 1 shows a first example, and

FIG. 2 shows a second example.

The illustration according to FIG. 1 shows that two faults F1 and F2 occurred simultaneously (F1: Cooling Sys Mv Trip and F2: Cooling Sys Vfd Trip). These faults are recorded as soon as they occur within one hour T2 and are recognized as faults. Up to three hours T3 prior to the first fault, the alarm Al Coolnt Tank Level <30 was triggered twice. Algorithm A concludes that this is a failure Q of the cooling system. In the period T3, for example, a first fault F1 could also have occurred, which has nothing to do with failure Q.

The illustration according to FIG. 2 shows that within two seconds T4 three different faults F4, F5 and F6 occurred: F4 input protection fault, F5 emergency stop remote and F6 emergency stop. Three hours T3 prior to the first fault F4, no alarms are found. Looking only at the “input protection fault”, an expert can conclude that the drive was stopped by a serious drive-related problem. However, “emergency stop remote” and “emergency stop” lead the algorithm to conclude that it is a manual stop of the drive. This is helpful because it prevents the search for a problem in the event log and directly allows the user to restart the converter.

For example, as a result, if the machine learning algorithm knows the faults and the warning that occurred during a failure, it can determine the cause of a previously unseen failure with >95% accuracy. For example, the machine learning algorithm used is based on a C-support vector classification. The root cause analysis can be selectively triggered for a single failure of the converter (specified as a critical log event) so that it is accessible to the service and the operator when needed.

What is claimed is:

1.-11. (canceled)

12. A method for event monitoring in a converter, comprising:
using log data of the converter which comprise labeling containing temporal information or relating to a sequence of logged messages pertaining to a fault or a warning and which prior to a start of the event monitoring do not show a fault for a predetermined time period after the start,
using for the event monitoring an evaluation of a combination of faults or warnings of at least a first type and of a second type, wherein the first fault type or warning type depends on a type of the converter, and the second fault type or warning type comprises user-defined faults and warnings,
generating user-defined messages based on a single signal or based on a combination of signals and using the user-defined messages for event monitoring in an individual environment of the converter,
determining a most probable technical root causes of a failure or a fault by using artificial intelligence,
training a machine learning algorithm and categorizing with the trained algorithm fault events into predefined cause categories,
training the artificial intelligence to indicate one or more fault sources based on a multiplicity of status messages, warning messages or fault messages, and
calculating in each case a probability for correctness of this indication.

13. The method of claim 12, wherein the log data are used after a start of the converter.

14. The method of claim 12, wherein the status messages, warning messages or fault messages are associated with the one or more fault sources.

15. The method of claim 14, further comprising calculating a probability for the association of the status messages, warning messages or fault messages with the one or more fault sources.

16. The method of claim 12, wherein the artificial intelligence is trained to perform the event monitoring.

17. A method for event monitoring in a converter, comprising:
recording messages of the converter, with the messages having a time stamp and an identification and the identification including a message type, a text or a source of a message;
detecting an event from a sequence of messages of a different type, wherein a message is a fault or a warning;
generating user-defined messages based on a single signal or based on a combination of signals;
using the user-defined messages for event monitoring in an individual environment of the converter,
determining a most probable technical root causes of a failure or a fault by using artificial intelligence;
training a machine learning algorithm to categorize fault events into predefined cause categories;
training the artificial intelligence so as to indicate one or more fault sources based on, wherein several fault sources can be indicated, and
calculating in each case a probability for correctness of this indication.

18. The method of claim 17, wherein the artificial intelligence is a cloud application, the method further comprising detecting with the artificial intelligence an output fault.

19. The method of claim 17, wherein the event monitoring is generated as set forth in claim 12.

20. Event monitoring of a converter, wherein the event monitoring comprises artificial intelligence and log file data from the converter are stored in a cloud, wherein the event monitoring is performed using a method as set forth in claim 12.

21. Event monitoring of a converter, wherein the event monitoring comprises artificial intelligence and log file data from the converter are stored in a cloud, wherein the event monitoring is performed using a method as set forth in claim 17.
